(19) United States
(12) Patent Application Publication
(10) Pub. No.: US 2001/0014111 A1
(43) Pub. Date: Aug. 16, 2001

(54) Method for measuring radiation temperature, equipment for measuring radiation temperature and equipment for manufacturing semiconductor device

(76) Inventor: Masahiro Shimizu, Nirasaki-shi (JP)

Correspondence Address: PILLSBURY WINTHROP LLP, 1600 TYSONS BOULEVARD, MCLEAN, VA, 22102, US

(21) Appl. No.: 09/784,011

(22) Filed: Feb. 16, 2001

(30) Foreign Application Priority Data
Feb. 16, 2000 (JP) 2000-38707

(51) Int. Cl. H01L 21/00; G01J 5/08; G01N 25/00; G01K 1/14

(52) U.S. Cl. 374/126; 156/345; 374/128; 374/9; 374/141

(57) ABSTRACT

To provide a method and equipment for measuring a radiation temperature both capable of measuring temperatures of a substrate more accurately and stably than ever and equipment for manufacturing semiconductors therein such a radiation temperature measuring method can be applied. A reflectometer 21 irradiates, on a wafer W having Si and SiO₂ layers, light of a wavelength that transmits the Si layer and is reflected from the SiO₂ layer (an interface between Si and SiO₂) to measure reflectance. With the reflectance and radiation energy at the wavelength of the wafer W measured by a radiation thermometer, a temperature of the wafer W is calculated. Thereby, even when a thin film is formed on a rear face of the substrate to blot and to result in a change of a state thereof, by the use of a stable interface in the substrate, temperatures can be measured with precision and stability.

### BACKGROUND OF THE INVENTION

1. Field of the Invention

The present invention relates to a method and equipment for measuring radiation temperatures of a semiconductor wafer (hereafter, simply referred to as a wafer) or a LCD substrate in the process of semiconductor manufacture, and equipment for manufacturing semiconductor devices where such a method for measuring radiation temperatures can be applied. In particular, the present invention relates to a method and equipment suitable for measuring radiation temperatures with high precision and stability, and semiconductor device manufacturing equipment therein such a method for measuring radiation temperatures is applicable.

2. Description-of the Related Art

In the process of manufacture of a semiconductor device or a LCD, with recent higher integration thereof, further microfabrication has been needed to form circuit patterns or the like. Accordingly, in various kinds of treatments, for instance in etching or thin film formation, an improvement in processing accuracy thereof is demanded.

Furthermore, in etching or thin film formation, a state of treatment such as treatment speed varies according to temperature of a substrate. Accordingly, in order to treat with high precision, a substrate temperature is necessary to be measured with accuracy.

As one of such methods for measuring substrate temperatures, a method for measuring radiation temperature by means of a radiation thermometer has been known. In the method for measuring radiation temperatures, an intensity of light of a prescribed wavelength radiated from a substrate is measured, on the basis of the measurement and emissivity of the substrate a temperature being calculated. The temperature measurement can be advantageously carried out from a distant place without coming into contact.

When measuring temperatures of a wafer or the like by the use of the aforementioned method for measuring radiation temperatures, on a front surface of the wafer various kinds of thin films are formed in multi-layers to cause an interference of light or the like in the thin films. Accordingly, a method for measuring radiation temperature that measures an intensity of light from a rear surface side of the wafer is disclosed in for example Japanese Patent Kokai No. HEI10-321539. According to the method, a rear surface side of a silicon wafer is smoothed, light of a wavelength of 0.1 to 1 μm radiated therefrom is measured to measure a temperature.

In the above temperature measurement of the Si wafer, light of a wavelength of 0.1 to 1 μm is employed. The reason for this is that in the wavelength of 0.1 to 1 μm, since transmittance of Si becomes zero, the relationship that reflectance+emissivity=1 holds.

Thus, in the existing method for measuring radiation temperatures, when measuring temperatures of Si wafer for instance, light of a wavelength 0.1 to 1 μm radiated from a rear face side of the Si wafer is measured to measure a temperature.

In the process of manufacture of a semiconductor device for instance, when a thin film is deposited on a front surface of a wafer by means of chemical vapor deposition (CVD) or the like, the thin film is deposited on the front surface of the wafer. However, even on a rear surface a thin film can formed a little. Furthermore, during transferring the wafer through the respective treatment steps, the rear surface of the wafer may be blotted or damaged, resulting in a change of surface roughness thereof.

Accordingly, even with the rear surface side of the wafer, the surface state thereof varies as the respective treatment steps proceed. Furthermore, variation thereof is not constant for each wafer. As a result, there are problems that variation of emissivity is caused to result in difficulties in measuring temperatures with stability and precision.

### SUMMARY OF THE INVENTION

The present invention is carried out with an intention to overcome the aforementioned problems. The object of the present invention is to provide a method and equipment for measuring radiation temperatures of a substrate with more accuracy and stability than ever, and equipment for manufacturing semiconductor device to which such a radiation temperature measuring method can be applied.

To overcome the aforementioned problems, a first aspect of the present invention set forth in claim 1 is a method for measuring radiation temperatures in which a substrate having a first layer and a second layer forming an interface with the first layer is a measuring object. The method comprises first and second steps. Here, in the first step, an amount of radiation of light of a wavelength that transmits the first layer and is reflected by the second layer is measured from the first layer side. In the second step, a temperature of the substrate is calculated from the measured amount of radiation and emissivity of the second layer.

That is, by paying attention to an interface of layers existing in a substrate that is a measuring object, an amount of radiation of light of a wavelength that transmits the first layer of the layers forming the interface and is reflected from the second layer is measured from the first layer side. Thereby, even when a rear surface of the substrate is made dirty due to the formation of a thin film to cause a change of the state thereof, by the use of a stable interface in the substrate, a temperature can be measured with precision and stability.

A second aspect of the present invention set forth in claim 2 is the method for measuring radiation temperatures set forth in claim 1. Wherein, the second step thereof comprises the steps of irradiating light, measuring an amount of reflected light, calculating reflectance of the interface, and obtaining emissivity of the second layer. In the step of irradiating light, the light of a wavelength that transmits the first layer and is reflected from the second layer is irradiated from the first layer side. In the step, of measuring an amount of reflected light, an amount of light reflected from the second layer of the irradiated light is measured. In the step of calculating reflectance of the interface, the reflectance of the interface between the first and second layers is calculated from the amounts of irradiated and measured reflected lights. In the step of obtaining emissivity of the second layer, the emissivity of the second layer is obtained from the calculated reflectance.

That is, since emissivity of a measuring object varies in general depending on temperature, the emissivity is estimated through measurement of the reflectance. Thereby, despite of the variation of the emissivity of a measuring object with temperature, operation and effect set forth in claim 1 can be attained.

A third aspect of the present invention is equipment for measuring radiation temperature set forth in claim 14 whose measuring object is a substrate having a first layer and a second layer that forms an interface with the first layer. Here, the equipment comprises an optical/electrical converter, and a temperature processor. The optical/electrical converter receives, on the first layer side, among light of wavelength that transmits the first layer and is reflected from the second layer, radiation from the substrate of wavelengths in the range of 8.8 μm to 9.8 μm and/or in the range of 16.1 μm to 16.6 μm to carry out optical/electrical conversion. The temperature processor calculates a temperature of the substrate from the output after the optical/electrical conversion with the emissivity of the second layer.

That is, in a certain kinds of substrates, when particular wavelengths (wavelengths in the range of 8.8 μm to 9.8 μm and/or in the range of 16.1 μm to 16.6 μm) are selected, there is a property that the emissivity hardly varies with the temperature. By making the use of this property, the radiation of the wavelength is measured to measure the substrate temperature. At that time, while paying attention to an interface of layers present in the substrate that is a measuring object, an amount of radiation of the light is measured from the first layer side. Thereby, despite of the change of the state due to formation of thin films on a rear surface of the substrate or blotting, temperatures can be measured with precision and stability.

A fourth aspect of the present invention is equipment for manufacturing semiconductor devices set forth in claim 17, the equipment comprising a radiation thermometer, a substrate susceptor, and a treatment chamber. The radiation thermometer is one for measuring radiation temperature whose measuring object is a substrate having a first layer and a second layer that forms an interface with the first layer, the radiation thermometer having an optical/electrical converter and a temperature, processor. The substrate susceptor supports the substrate on the first layer side, the treatment chamber treating the substrate. The optical/electrical converter receives, on the first layer side, among light of a wavelength that transmits the first layer and is reflected from the second layer, radiation of wavelengths in the range of 8.8 μm to 9.8 μm and/or in the range of 16.1 μm to 16.6 μm from the substrate to carry out optical/electrical conversion. The temperature processor calculates a temperature of the substrate from the output after the optical/electrical conversion with the emissivity of the second layer.

In addition in this case, a property is utilized that in a certain kinds of substrates, when particular wavelengths (wavelengths in the range of 8.8 μm to 9.8 μm and/or in the range of 16.1 μm to 16.6 μm) are selected, the emissivity does hardly vary with the temperature. In the equipment for manufacturing semiconductor devices, while supporting the substrate on the first layer side, the radiation of the particular wavelength is measured on the first layer side. At that time, by the use of a stable interface in the substrate, despite of the change of the state due to formation of thin films on a rear surface of the substrate or blotting, temperatures can be measured with precision and stability.

### BRIEF DESCRIPTION OF THE DRAWINGS

FIG. 1A is a diagram for explaining an embodiment of the present invention.

FIG. 1B is a diagram for explaining an embodiment of the present invention different from one shown in FIG. 1A.

FIG. 2 is a diagram showing the relationship between light wavelength and transmittance of Si and SiO₂.

FIG. 3 is a diagram for explaining an embodiment in which the present method for measuring radiation temperatures is applied in temperature measurement of a wafer where shallow trench isolation is applied.

FIG. 4 is a diagram for explaining an embodiment of the present invention different from ones shown in FIGS. 1A and 1B.

FIG. 5 is a schematic front section showing an embodiment of heat treatment equipment that is equipment for manufacturing semiconductor devices of the present invention.

FIG. 6 is a schematic perspective view showing the surroundings of a susceptor of the heat treatment equipment shown in FIG. 5.

FIG. 7 is a diagram showing spectral emissivity of a SOI semiconductor wafer.

FIG. 8 is a diagram showing spectral emissivity of a SOI semiconductor wafer different in the manufacturing method from that of the SOI semiconductor wafer shown in FIG. 7.

FIG. 9 is a diagram showing spectral emissivity of a Si semiconductor wafer.

FIG. 10 is a diagram showing spectral emissivity of a Si semiconductor wafer different in a doped amount of impurity from that shown in FIG. 9, the impurity concentration being lower by approximately 10⁻³ times than that shown in FIG. 9.

### DESCRIPTION OF PREFERRED EMBODIMENTS

As a preferable embodiment of the present invention, in a method for measuring radiation temperature set forth in claim 1, the substrate is a semiconductor wafer.

Furthermore, as a preferable embodiment of the present invention, in a method for measuring radiation temperature set forth in claim 1, the substrate is a SOI semiconductor wafer.

Furthermore, as a preferable embodiment of the present invention, in a method for measuring radiation temperature set forth in claim 2, the substrate is a SOI semiconductor wafer.

Still furthermore, as a preferable embodiment of the present invention, in a method for measuring radiation temperature set forth in claim 4, in the first step, the first layer side corresponds to a rear surface of the SOI semiconductor wafer.

Furthermore, as a preferable embodiment of the present invention, in a method for measuring radiation temperature set forth in claim 5, in the first and second steps, the first layer side corresponds to a rear surface of the SOI semiconductor wafer.

Furthermore, as a preferable embodiment of the present invention, in a method for measuring radiation temperature set forth in claim 1, the first and second layers are any different two layers selected from Si, SiO₂, SiON, SiN, TiSi and doped layers.

Still furthermore, as a preferable embodiment of the present invention, in a method for measuring radiation temperature set forth in claim 1, the first layer is a layer of Si, the second layer being a layer of SiO₂.

Furthermore, as a preferable embodiment of the present invention, in a method for measuring radiation temperature set forth in claim 1, in the first step, the wavelength is in the range of 8.8 μm to 9.8 μm.

Still furthermore, as a preferable embodiment of the present invention, in a method for measuring radiation temperature set forth in claim 1, in the first step, the wavelength is in the range of 16.1 μm to 16.6 μm.

Furthermore, as a preferable embodiment of the present invention, in a method for measuring radiation temperature set forth in claim 2, the substrate is heated to a temperature of 400° C. or more, in the first and second steps the wavelength being in the range of 5.5 μm to 8.8 μm.

Furthermore, as a preferable embodiment of the present invention, in a method for measuring radiation temperature set forth in claim 2, the substrate is heated to a temperature of 400° C. or more, in the first and second steps the wavelength being in the range of 9.8 μm to 16.1 μm.

Still furthermore, as a preferable embodiment of the present invention, in a method for measuring radiation temperature set forth in claim 14, the substrate is a SOI semiconductor wafer.

Still furthermore, as a preferable embodiment of the present invention, in a method for measuring radiation temperature set forth in claim 14, the first layer is a layer of Si, the second layer being a layer of SiO₂.

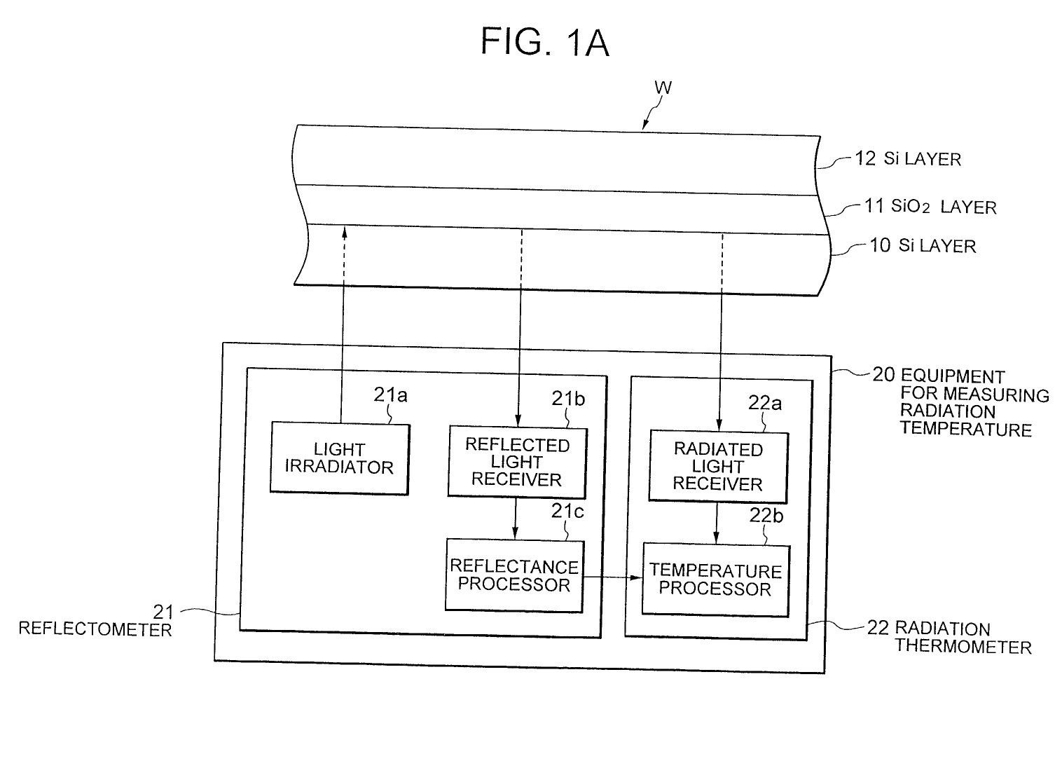

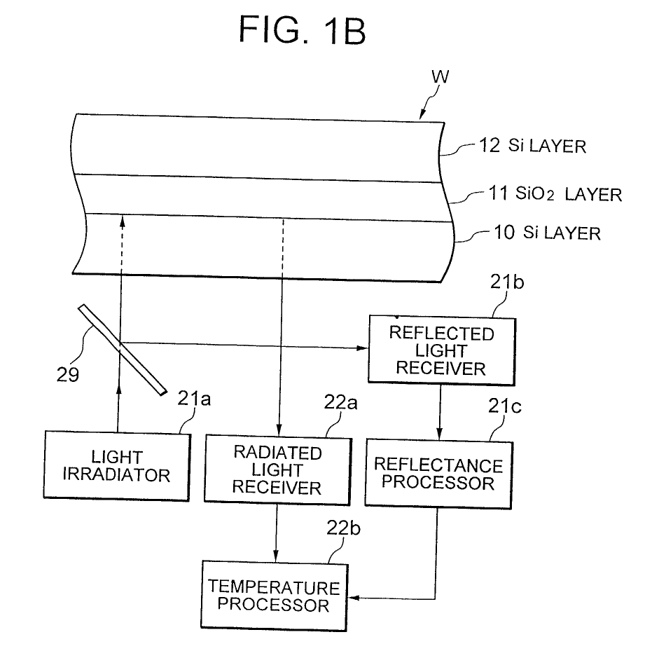

In the following, embodiments of the present invention will be explained with reference to the drawings. FIG. 1A is a diagram for explaining an embodiment in which the present method for measuring radiation temperature is applied in temperature measurement of a SOI wafer.

As shown in FIG. 1A, a wafer W, which is a SOI (Silicon On Insulator) wafer, is constituted in a three-layered structure of the lower most layer of a Si layer 10, a SiO₂ layer 11 that is a upper layer of the Si layer 10, and a Si layer 12 that is a upper layer of the SiO₂ layer 11.

In the present embodiment, light of a wavelength that can transmit the Si layer 10 as the first layer and is reflected by the SiO₂ layer 11 (an interface between the Si layer 10 and the SiO₂ layer 11) as the second layer is employed. With the light, from a rear surface side (Si layer 10 side) of the wafer W, a temperature T of the wafer W is measured. That is, the light of the wavelength is used in reflectance measurement as well as a target wavelength when receiving radiation from the wafer W.

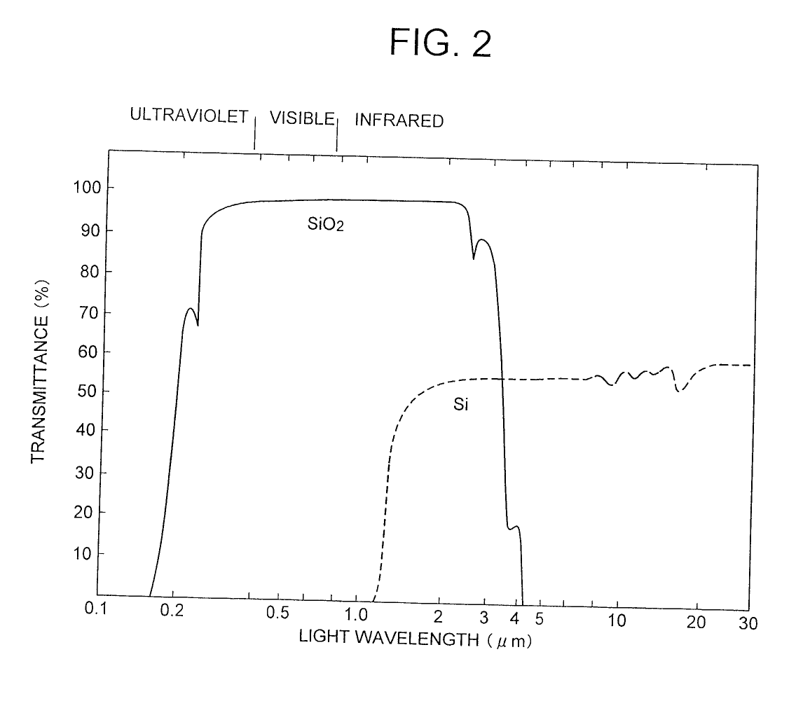

FIG. 2 is a diagram showing the relationship between wavelength (abscissa) and transmittances (ordinate) of Si and SiO₂ As shown with a dotted line in the figure, when the wavelength is approximately 1 μm or less, the transmittance of Si is almost zero. Accordingly, to select light that can transmit Si, it is necessary to select light of a wavelength of approximately 1 μm or more.

Furthermore, as shown with a solid line in the figure, transmittance of SiO₂ is high in the range of from approximately 0.2 μm to approximately 4 μm. Accordingly, in order to select light that does not transmit SiO₂ but is reflected on a surface of SiO₂, it is necessary to select light of a wavelength of approximately 0.2 μm or less or approximately 4 μm or more.

Accordingly, as the light that transmits the Si layer 10 and is reflected from the SiO₂ layer 11 (an interface between the Si layer 10 and the SiO₂ layer 11), it is necessary to employ the light of a wavelength of approximately 4 μm or more.

In addition when the temperature measurement is carried out with layers of other materials such as SiON, SiN, TiSi and doped layers as the first and second layers, similarly with the above, a wavelength of light to use can be selected.

Next, measurement equipment used in the measurement of temperatures of the wafer will be explained. As shown in FIG. 1A, for instance, a measuring device of a configuration like equipment for measuring radiation temperature 20 can be used.

The equipment for measuring radiation temperatures 20 is constituted of a reflectometer 21 and a radiation thermometer 22. The reflectometer 21 measures reflectance of the wafer W. The radiation thermometer 22 measures radiation energy from the wafer W to calculate a temperature of the wafer W based on the emissivity obtained from the reflectance measured by the reflectometer 21.

The aforementioned reflectometer 21 is configured of a light irradiator 21a, a reflected light receiver 21b and a reflectance processor 21c. The light irradiator 21a consists of a light-emitting element or the like for irradiating light from a rear surface side of the wafer W through the Si layer 10 on the SiO₂ layer 11. The reflected light receiver 21b consists of a light receiving element or the like that receives the light reflected from the SiO₂ layer 11 (an interface between the Si layer 10 and the SiO₂ layer 11) to convert into electrical signal. The reflectance processor 21c processes the reflectance of the SiO₂ layer 11 (an interface between the Si layer 10 and the SiO₂ layer 11) based on the signal from the reflected light receiver 21b.

For convenience sake of reflectance measurement, the light irradiator 21a may irradiate the light slantingly onto the wafer W, and the reflected light receiver 21b may be disposed at the position where regular reflection light reaches.

The aforementioned radiation thermometer 22 is constituted of a radiated light receiver 22a and a temperature processor 22b. The radiated light receiver 22a consists of a light receiving element or the like that receives the light radiated from the wafer W (mainly SiO₂ layer 11) to convert into electric signal and output the electric signal proportional to the radiation energy. The temperature processor 22b calculates a temperature of the wafer W from the electric signal from the radiated light receiver 22a and the reflectance (emissivity obtained from the reflectance) measured by the reflectometer 21.

By the use of the equipment for measuring radiation temperature 20 mentioned in the above, a temperature of a wafer W can be measured in the following way.

First, by means of the light irradiator 21a of the reflectometer 21, light having a prescribed wavelength in the aforementioned wavelength range is irradiated from a rear surface side of the wafer W through the Si layer 10 on the SiO₂ layer 11 (an interface between the Si layer 10 and the SiO₂ layer 11).

Then, the light that is reflected at the SiO₂ layer 11 (an interface between the Si layer 10 and the SiO₂ layer 11) and enters through the Si layer 10 in the reflected light receiver 21b is measured. Thereby, the reflectance of the light of aforementioned prescribed wavelength X is calculated at the reflectance processor 21c.

In general, with an intensity (light flux) Φ1 of incident light and an intensity (light flux) Φ2 of reflected light, reflectance ρ can be expressed by

ρ=φ2/φ1.

Next, of the aforementioned prescribed wavelength λ, the radiation energy from the wafer W is measured by means of the radiated light receiver 22a.

The radiation energy, as mentioned above, is an energy of the light having the wavelength λ whose transmittance in the Si layer 10 is high (low emissivity). Accordingly, it shows the radiation energy mainly from the SiO₂ layer 11.

Then, from the radiation energy measured by the aforementioned radiated light receiver 22a and the reflectance (emissivity obtained from the reflectance) measured by the reflectometer 21, at the temperature processor 22b, a temperature of the wafer W is calculated.

There is the following relationship between the aforementioned reflectance ρ and emissivity ε and transmittance τ, that is

ρ+ε+τ=1.

When the transmittance τ is zero, the relationship reduces to

ρ+ε=1.

Accordingly, from the reflectance ρ, the emissivity ε can be obtained.

With the measured radiation energy and the obtained emissivity, by applying Stefan-Boltzmann law

E=εσT⁴ (E is total energy and σ is a constant)

to the aforementioned prescribed wavelength, a temperature T can be calculated.

According to the present embodiment explained in the above, with light of a wavelength that transmits through the Si layer 10 of the wafer Wand is reflected at the SiO₂ layer 11 (an interface between the Si layer 10 and the SiO₂ layer 11), a temperature T of the wafer W is measured from a rear surface side of the wafer W (Si layer 10 side). Accordingly, even when the rear surface of the wafer W is covered by a thin film, blotted or damaged, the temperature can be measured by means of the light from the stable interface that is formed inside the wafer W between the Si layer 10 and the SiO₂ layer 11 and does not undergo a change of state. Accordingly, the temperature measurement can be implemented with more precision and stability than ever.

In addition, in the above embodiment, light of a wavelength of 4 μm or more that is much abundant in an amount of radiation compared with that of short wavelength of 1 μm or less that is so far used in the temperature measurement of the Si wafer is employed. As a result, S/N ratio can be improved, resulting in the temperature measurement with higher precision than ever.

Furthermore, in the above embodiment, the temperature is measured from the rear surface side (Si layer 10 side) of the wafer W. However, the temperature can be similarly measured from the front surface side (Si layer 12 side) of the wafer W. In that case, light that transmits the Si layer 12 as the first layer and is reflected from the SiO₂ layer 11 (an interface between the Si layer 12 and the SiO₂ layer 11) as the second layer is measured.

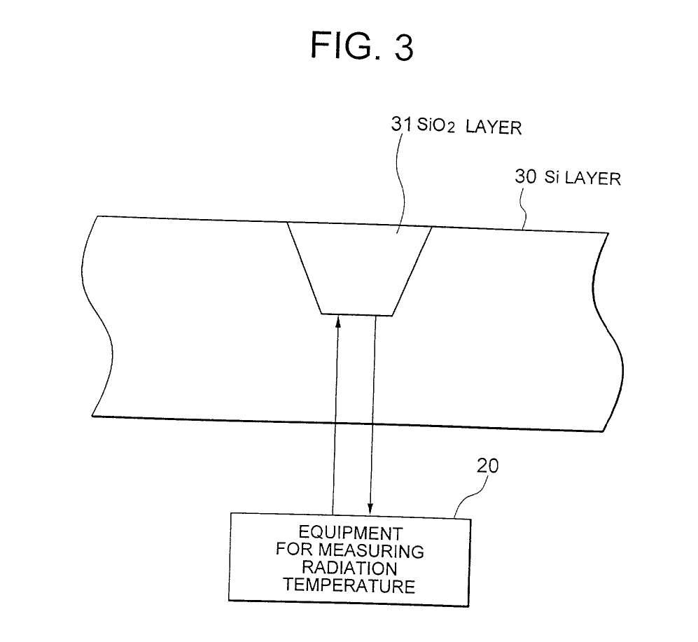

Furthermore, in the aforementioned embodiment, the temperature measurement of the SOI wafer is explained. However, when an interface of layers consisting of different materials is formed inside, an ordinary wafer also, other than the SOI wafer, can be used. For instance, FIG. 3 shows schematically a sectional structure of a wafer W in which for shallow trench isolation (STI) purpose, on a Si layer 30 a trench of flat bottom is formed and therein a SiO₂ layer 31 is formed. When constituted thus, a flat interface is formed between the bottom of the SiO₂ layer 31 and the Si layer 30. Accordingly, by measuring the light from the part of the interface from a rear surface side of the wafer W or the like, similarly with the aforementioned SOI wafer, the temperature measurement can be implemented.

Still further, in the aforementioned embodiment, the first layer is the Si layer 10 and the second layer is the SiO₂ layer 11. However, the first layer may be a SiO₂ layer and the second layer may be a Si layer. Alternatively, the first and second layers may be different two layers of other materials for instance such as SiON, SiN, TiSi, and doped layers.

Next, a modification example of the embodiment shown in FIG. 1A will be explained with reference to FIG. 1B. FIG. 1B is a diagram for explaining an embodiment in which the present method for measuring radiation temperature, different from one shown in FIG. 1A, is applied in measuring the temperature of a SOI wafer. In the following, an explanation will be given to part different from the embodiment shown in FIG. 1A.

In the present embodiment, the reflectometer is similarly constituted with one shown in FIG. 1A. That is, the reflectometer comprises a light irradiator 21a, a reflected light receiver 21b and a reflectance processor 21c. The light irradiator 21a consists of a light-emitting element or the like for irradiating light from a rear surface side of the wafer W through the Si layer 10 on the SiO₂ layer 11. The reflected light receiver 21b consists of a light receiving element or the like that receives the light reflected from the SiO₂ layer 11 (an interface between the Si layer 10 and the SiO₂ layer 11) to convert into electrical signals. The reflectance processor 21c processes reflectance of the SiO₂ layer 11 (an interface between the Si layer 10 and the SiO₂ layer 11) based on the signal from the reflected light receiver 21b.

Here, irradiation light from the light irradiator 21a transmits a transmitter/reflector plate (half mirror) 29 to reach a wafer W. Reflected light from the SiO₂ layer 11 (an interface between the Si layer 10 and the SiO₂ layer 11) is reflected by the transmitter/reflector plate (half mirror) 29 to be received by the reflected light receiver 21b. Thereby, the light irradiator 21a and the reflected light receiver 21b can be differently arranged in their positions to result in a compact configuration. Accordingly, temperature measurement equipment can be more easily configured.

As mentioned in the explanation of FIGS. 1A and 1B, the reflectometer is used to measure reflectance of the SiO₂ layer 11 (an interface between the Si layer 10 and the SiO₂ layer 11) to obtain emissivity from the reflectance. Accordingly, when the emissivity is known and constant of the measuring object, the reflectometer 21 can be omitted to permit implementing the temperature measurement only by measuring an amount of radiation by means of the radiation thermometer 22.

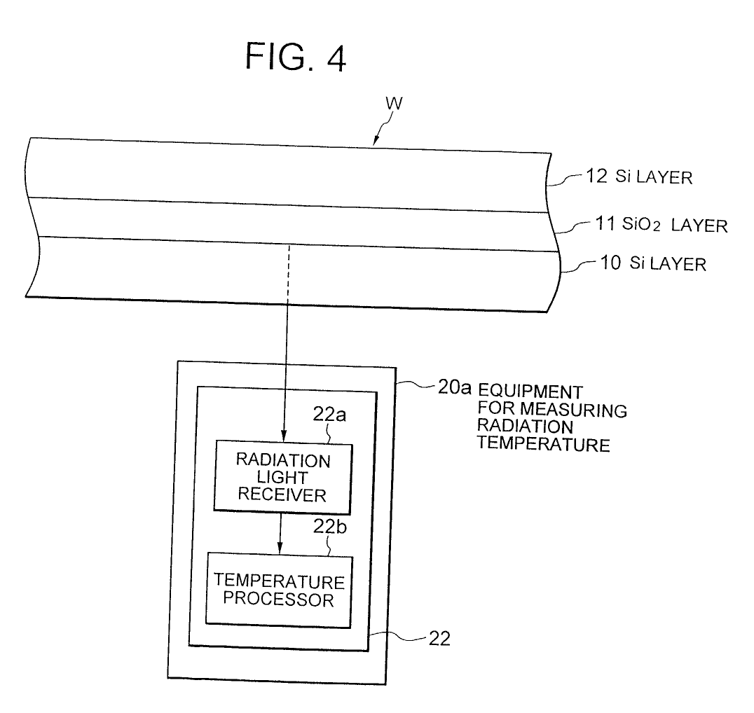

The equipment for measuring radiation temperature in such a case, as one example, can be configured like a code 20a shown in FIG. 4. This figure is a diagram for explaining an embodiment of the present embodiment, different from ones shown in FIGS. 1A and 1B, constituent elements so far explained being given of the same codes.

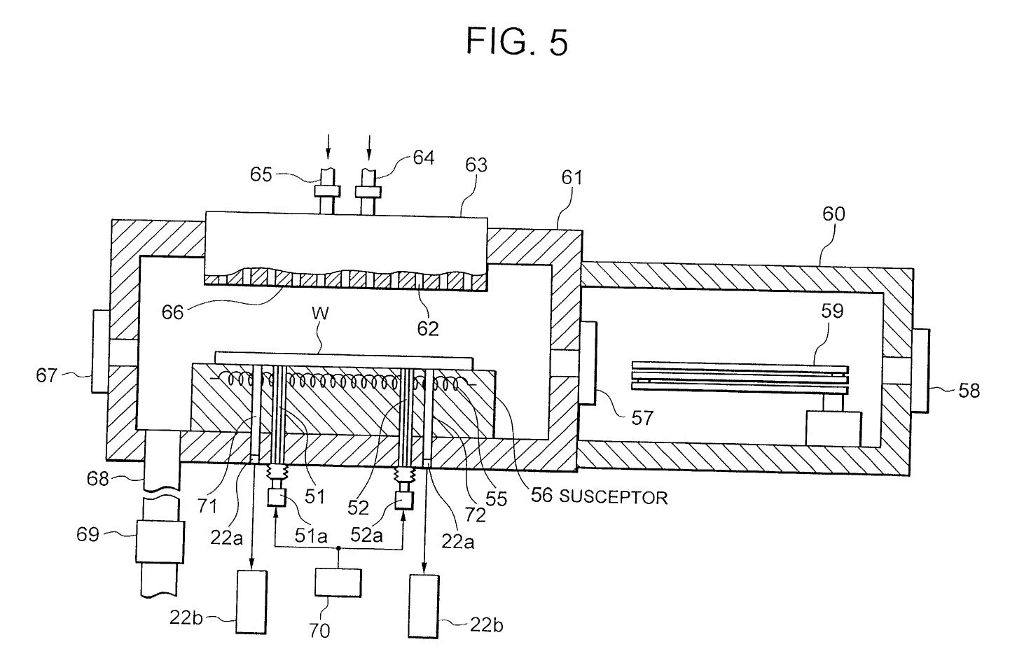

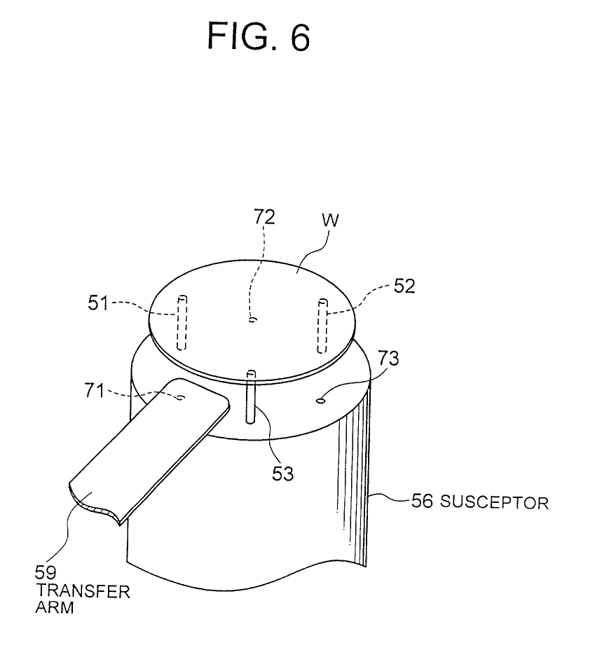

Next, with heat treatment equipment as an illustration of the present equipment for manufacturing semiconductor devices, an embodiment thereof will be explained with reference to FIGS. 5 and 6.

FIG. 5 is a schematic front section showing an embodiment of the heat treatment equipment that is the present equipment for manufacturing semiconductor devices. In the figure, reference numeral 61 denotes a treatment chamber structured airtight. On a side wall surface thereof 61, gate valves 57 and 67 are disposed to seal the inside airtight, furthermore to a base thereof 61 an exhaust pipe 68 being connected with a vacuum pump 69 interposed.

On the basal center in the treatment chamber 61, for instance a cylindrical susceptor 56 is disposed, thereon 56 a ceramic heater where a heater such as a resistance heater 55 is built in a ceramic body being disposed. Furthermore, to the susceptor 56, three pieces of elevating pins 51, 52 and 53 for instance are provided with, as shown in FIG. 6 for instance, so that a face of the susceptor 56 is divided in a circumferential direction into three equal parts.

These elevating pins 51, 52 and 53 constitute an elevator, each of these pins being constituted so as to elevate simultaneously by means of elevation mechanism, for instance air cylinders 51a, 52a, - - - based on control signal from a controller 70. These elevating pins 51, 52 and 53 are normally in readiness in positions buried from the face of the susceptor 56. However, the elevating pins, when ascending, are projected from the susceptor face to hold a rear surface of the wafer W.

Furthermore, on the susceptor 56, radiated light holes 71, 72 and 73 leading to the radiated light receiver 22a are disposed as shown in FIG. 6 for instance. That is, these light holes 71, 72 and 73 are disposed alternately arranged with the elevating pins 51, 52 and 53 to divide equally the face of the susceptor 56 into three in a circumferential direction. The radiated light receiver 22a receives light of a particular wavelength radiated from a rear face of the wafer W disposed on the susceptor 56 to lead electric signal converted as a result of the reception to a temperature processor 22b. Functions of the radiated light receiver 22a and temperature processor 22b are the same with that shown in FIGS. 1A, 1B and 4.

In the present embodiment, the temperatures are measured of three points on a rear face of the wafer W. However, the number of the points to measure may be larger or smaller than that. Furthermore, the positions to dispose may be selected so as to show most accurately a nominal temperature of the entire wafer

At the upper portion of the treatment chamber 61, a gas feeder 63 is disposed so as to face the susceptor 56. The gas feeder 63 is furnished with a gas diffuser 66 in which many gas injection holes 62 are formed, for instance treatment gases sent from gas feed pipes 64 and 65 respectively being fed separately through the gas injection holes 62 into the treatment chamber 61. Furthermore, on one side wall face of the treatment chamber 61, a load lock chamber 60 is connected through the gate valve 57, therein a transfer arm 59 that is a transfer means of the wafer W being disposed. Reference numeral 58 in the figure is the gate valve interposed between the load lock chamber 60 and the atmosphere. Though omitted in the figure for convenience sake, also on the gate valve 67 side, a load lock chamber is disposed.

In such the heat treatment equipment, various kinds of heat treatments can be implemented. The followings are cited as examples. For instance, on a wafer W thereon a SiO₂ film is formed, with for instance mono-silane gas (SiH₄) and phosphine gas (PH₃) as the treatment gas (film formation gas), a poly-silicon film doped by phosphorous can be formed. Alternatively, an etching gas is introduced into the treatment chamber 61 evacuated through the exhaust 68 by means of a vacuum pump 69 to etch a treatment surface of the wafer W.

In the above heat treatments, preceding the aforementioned treatment of the wafer W, by means of the transfer arm 59, the wafer W is transferred from the load lock chamber 60 into the treatment chamber 61. At that time, the elevating pins 51, 52 and 53 are projected from the susceptor 56 face by means of the air cylinders 51a, 52a, - - - , thereby the wafer w being delivered to the elevating pins 51, 52 and 53. When transferring the treated wafer W out of the treatment chamber 61, the elevating pins 51, 52 and 53 and the transfer arm 59 are operated in an opposite turn.

During the treatment of the wafer W, by means of the radiated light receiver 22a and the temperature processor 22b that constitute radiation temperature measuring equipment, while measuring the temperature of the wafer W as mentioned above, the treatment can be implemented. Thereby, with precision and stability, the temperature of the wafer W can be controlled, various kinds of treatments can be applied to the wafer W with high precision and reproducibility, accordingly.

As the semiconductor manufacturing equipment, other than the aforementioned heat treatment equipment, even in plasma etching, chemical vapor deposition, plasma CVD, sheet-fed CVD equipment and coating/developing equipment in resist coating and development treatment, similarly the temperature measurement of the treating substrate can be implemented.

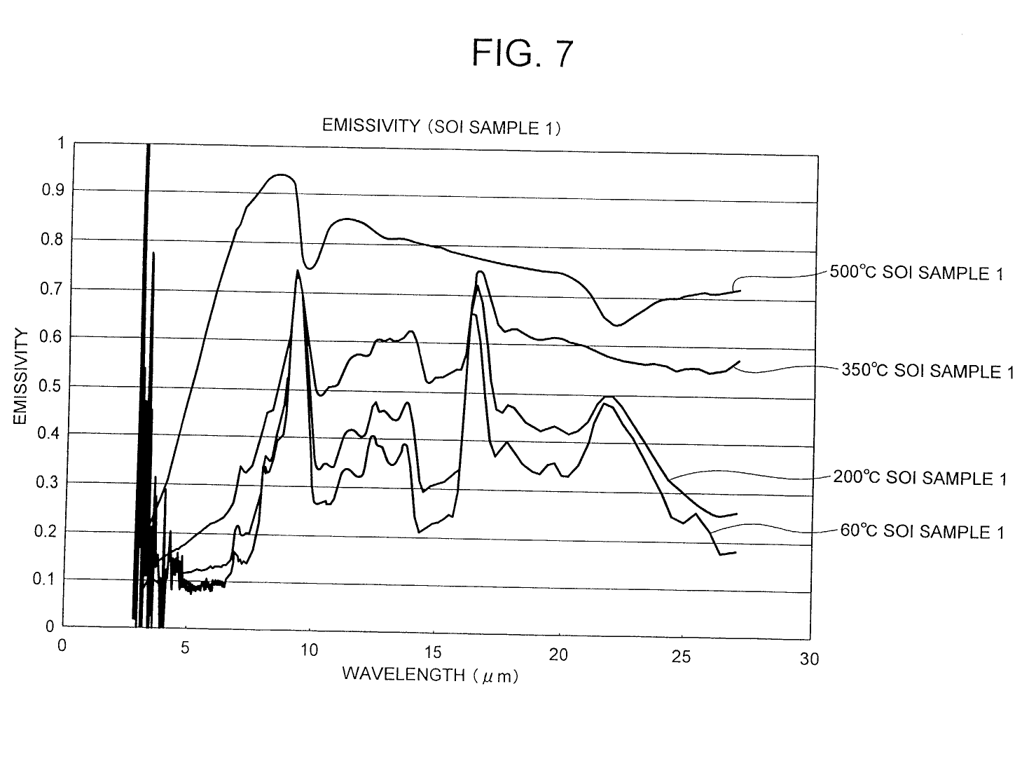

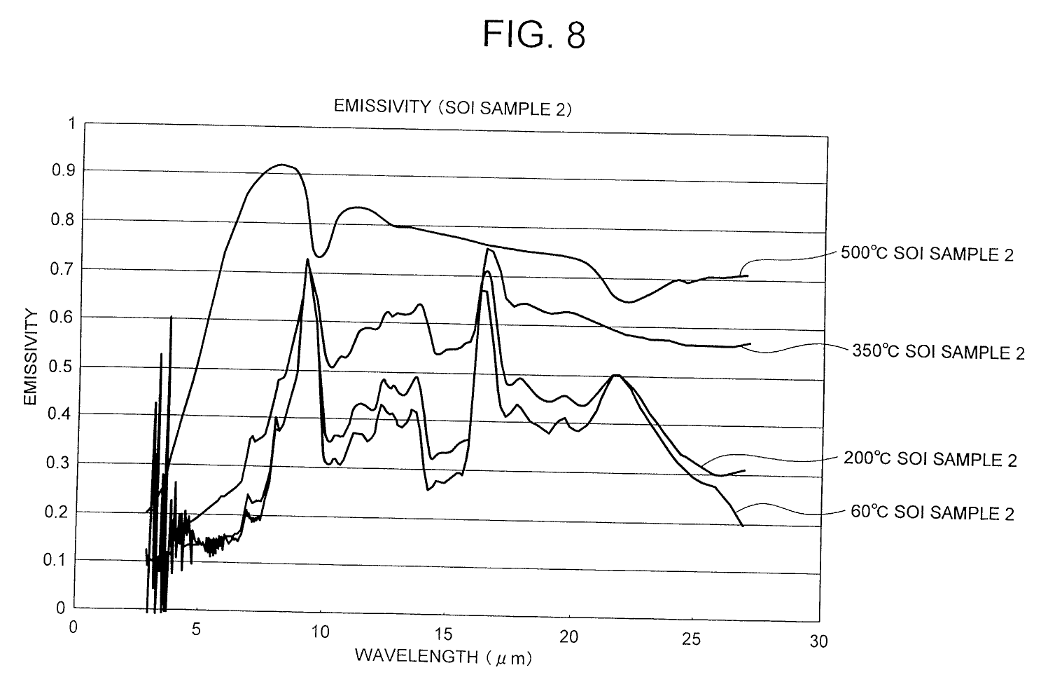

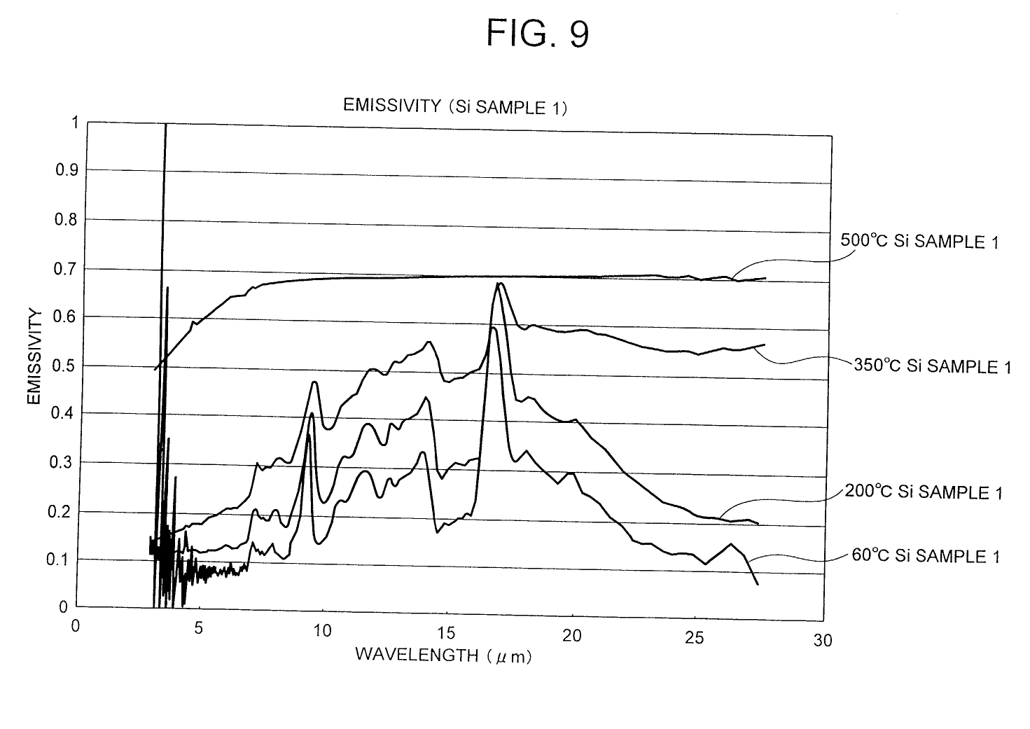

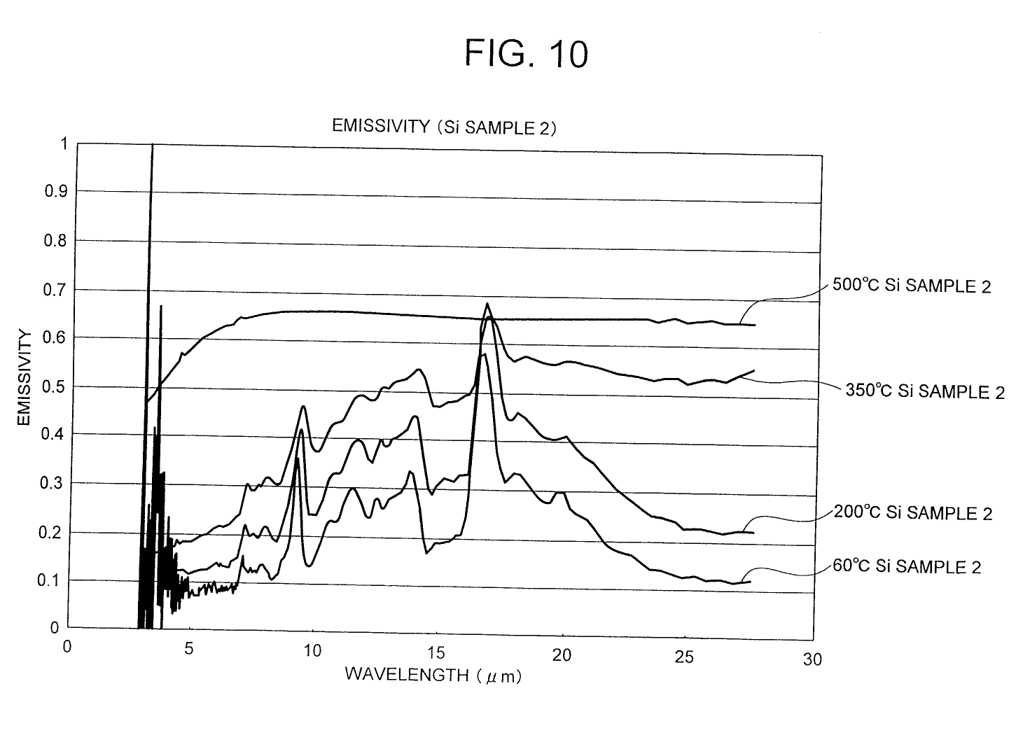

Next, for the case of a SOI semiconductor wafer being a measuring object, the preferable range of the aforementioned prescribed wavelength (4 μm or more) will be further detailed with reference to FIGS. 7, 8, 9 and 10. FIGS. 7 and 8 show data of spectral emissivity of the SOI semiconductor wafer measured at various temperatures, FIGS. 9 and 10 showing data of spectral emissivity of a Si wafer measured at various temperatures.

The difference between target samples in FIGS. 7 and 8 exists in manufacturing method thereof, roughly speaking, the SOI semiconductor wafer in FIG. 7 being manufactured by sticking an insulating layer and a semiconductor layer, further followed by after treatment. On the other hand, in the SOI semiconductor wafer in FIG. 8, oxygen atoms are implanted into a semiconductor layer, followed by heat treating to form an insulating layer in the semiconductor layer. At present, as the SOI semiconductor wafer, the above two kinds can be available.

The difference between the target samples in FIGS. 9 and 10 exists in an impurity concentration in Si. One shown in FIG. 9 contains an impurity of higher concentration by approximately 10³ times than that shown in FIG. 10. Any of these is the ordinarily used wafer.

As obvious from the comparison of FIGS. 7 and 8, the spectral emissivity of the SOI semiconductor at each temperature is almost the same despite of the difference of the manufacturing method thereof. Accordingly, in determining the preferable range of the aforementioned prescribed wavelength, the difference can be neglected.

When compared FIGS. 7, 8 and FIGS. 9, 10, firstly, in the range of wavelength of 5.5 μm to 8.8 μm, in particular at 500° C., the emissivity of the SOI semiconductor wafer can be read large. That is, when, of the light radiated from the SOI semiconductor wafer, the wavelength in the above range is taken as the aforementioned prescribed wavelength, the measurement can be implemented with high radiation energy and excellent S/N ratio. A tendency of the emissivity becoming high in the above range, as obvious from the comparison between these figures, can be recognized even at the temperature of approximately 350° C., but becoming more conspicuous at 400° C. or more.

Accordingly, when measuring the temperature of 400° C. or more, the wavelength of 5.5 μm to 8.8 μm can be selected as one of the preferable ranges of the aforementioned prescribed wavelength. At the wavelength, the emissivity varies due to temperature, it is suitable to calculate the emissivity through measurement of reflectance, accordingly.

Furthermore, secondly, in the range of 9.8 μm to 16.1 μm, the utterly same can be said. Accordingly, when measuring the temperatures of 400° C. or more, the wavelength in the range of 9.8 μm to 16.1 μm can be selected as another preferable range of the aforementioned prescribed wavelength. Even at the wavelength, the emissivity varies due to temperature. Accordingly, it is suitable to calculate the emissivity through measurement of reflectance.

Furthermore, thirdly, in the wavelength of 8.8 μm to 9.8 μm, in the case of the SOI semiconductor wafer, it can be read that the emissivity hardly changes due to the temperature and is high in level. That is, when of the light radiated from the SOI semiconductor wafer, the wavelength in the above range is taken as the aforementioned prescribed wavelength, the measurement can be carried out with high radiation energy and excellent S/N ratio. In addition to the above, the process of calculating the emissivity through measurement of reflectance can be omitted. Accordingly, the wavelength of 8.8 μm to 9.8 μm can be selected as still another one of the preferable ranges of the aforementioned prescribed wavelength, at that time, the radiation temperature measuring equipment being configured with simplicity.

In addition, fourthly, even in the wavelength of 16.1 μm to 16.6 μm, though not so small as in the wavelength of 8.8 μm to 9.8 μm in the temperature variation of the emissivity, the approximately same with the above can be said. Accordingly, the wavelength of 16.1 μm to 16.6 μm can be selected as still another one of the preferable ranges of the aforementioned prescribed wavelength, at that time too, the radiation temperature measuring equipment being configured with simplicity.

As detailed in the above, according to the present invention, a method and equipment for measuring radiation temperature both enabling to measure a substrate temperature with more precision and stability than ever, and semiconductor manufacturing equipment where such a radiation temperature measuring method can be applied can be obtained.

Although the present invention has been shown and described with respect to a best mode embodiment thereof, it should be understood by those skilled in the art that the foregoing and various other changes, omissions, and additions in the form and detail thereof may be made therein without departing from the spirit and scope of the present invention.

What is claimed is:

1. A method for measuring a radiation temperature where a substrate having a first layer and a second layer that forms an interface with the first layer is a measuring object, the method comprising the steps of:
measuring, from the first layer side, an amount of radiation of light of a wavelength that transmits the first layer and is reflected by the second layer; and
calculating a temperature of the substrate from the measured amount of radiation and emissivity of the second layer.

2. The method for measuring a radiation temperature as set forth in claim 1:
wherein the second step includes the steps of;
irradiating a light of a wavelength that transmits the first layer and is reflected by the second layer from the first layer side;
measuring an amount of light reflected from the second layer of the irradiated light;
calculating reflectance of the interface between the first and second layers from the amounts of the irradiated light and the measured reflected light; and
obtaining the emissivity of the second layer from the calculated reflectance.

3. The method for measuring a radiation temperature as set forth in claim 1:
wherein the substrate is a semiconductor wafer.

4. The method for measuring a radiation temperature as set forth in claim 1:
wherein the substrate is a SOI semiconductor wafer.

5. The method for measuring a radiation temperature as set forth in claim 2:
wherein the substrate is a SOI semiconductor wafer.

6. The method for measuring a radiation temperature as set forth in claim 4:
wherein in the first step, the first layer side corresponds to a rear face of the SOI semiconductor wafer.

7. The method for measuring a radiation temperature as set forth in claim 5:
wherein in the first and second steps, the first layer side corresponds to a rear face of the SOI semiconductor wafer.

8. The method for measuring a radiation temperature as set forth in claim 1:
wherein the first and second layers are any different two layers of Si, SiO₂, SiON, SiN, TiSi and doped layers.

9. The method for measuring a radiation temperature as set forth in claim 1:
wherein the first layer is a Si layer, the second layer being a SiO₂ layer.

10. The method for measuring a radiation temperature as set forth in claim 1:
wherein in the first step, the wavelength is in the range of 8.8 μm to 9.8 μm.

11. The method for measuring a radiation temperature as set forth in claim 1:
wherein in the first step, the wavelength is in the range of 16.1 μm to 16.6 μm.

12. The method for measuring a radiation temperature as set forth in claim 2:
wherein the substrate is heated at a temperature of 400° C. or more; and
in the first and second steps, the wavelength is in the range of 5.5 μm to 8.8 μm.

13. The method for measuring a radiation temperature as set forth in claim 2:
wherein the substrate is heated at a temperature of 400° C. or more; and
in the first and second steps, the wavelength is in the range of 9.8 μm to 16.1 μm.

14. Equipment for measuring a radiation temperature where a substrate having a first layer and a second layer that forms an interface with the first layer is a measuring object, the equipment comprising:
an optical/electrical converter that receives, at the first layer side, radiation of light from the substrate, the light transmitting the first layer and being reflected by the second layer, and being in a range of wavelength of 8.8 μm to 9.8 μm and/or of wavelength of 16.1 μm to 16.6 μm, to carry out optical/electrical conversion; and
a temperature processor for calculating the temperature of the substrate from an output after the optical/electrical conversion with emissivity of the second layer.

15. The equipment for measuring a radiation temperature as set forth in claim 14:
wherein the substrate is a SOI semiconductor wafer.

16. The equipment for measuring a radiation temperature as set forth in claim 14:
wherein the first layer is a Si layer, the second layer being a SiO₂ layer.

17. Semiconductor manufacturing equipment, comprising:
a radiation thermometer whose measuring object is a substrate having a first layer and a second layer that forms an interface with the first layer, the radiation thermometer including (i) an optical/electrical converter that receives, at the first layer side, radiation of light from the substrate, the light transmitting the first layer and being reflected by the second layer, and being in the range of a wavelength of 8.8 μm to 9.8 μm and/or of a wavelength of 16.1 μm to 16.6 μm, to carry out optical/electrical conversion and (ii) a temperature processor for calculating a temperature of the substrate from an output after the optical/electrical conversion with emissivity of the second layer;
a substrate susceptor for supporting the substrate at the first layer side; and
a treatment chamber that accommodates the substrate susceptor and treats the substrate.
